(19) United States
(12) Patent Application Publication
(10) Pub. No.: US 2003/0194885 A1
(43) Pub. Date: Oct. 16, 2003

(54) Electrical connector assembly and cap connector

(76) Inventor: Koichi Iino, Kanagawa (JP)

Correspondence Address: Barley, Snyder, Senft & Cohen, LLC, 5 Westlakes Suite 275, 1000 Westlakes Drive, Berwyn, PA, 19312, US

(21) Appl. No.: 10/412,552

(22) Filed: Apr. 11, 2003

(30) Foreign Application Priority Data
Apr. 11, 2002 (JP) 2002-109318

(51) Int. Cl. H05K 1/00; H01R 12/00

(52) U.S. Cl. 439/74

(57) ABSTRACT

An electrical connector assembly provided with a plug connector and a cap connector. The plug connector includes an insulative plug housing with an engagement protrusion and a plurality of elastic first contacts. The cap connector includes an insulative cap housing with an engagement recess for receiving the engagement protrusion. Planar second contacts are arranged within the engagement recess. Each of the second contacts has a pair of contact portions that maintains an interval therebetween. One of the pair of contact portions contacts the first contacts and the other of the pair of contact portions contacts the engagement protrusion to support a biasing force caused by the contact of the first and second contacts when the plug connector and the cap connector are engaged.

### BACKGROUND OF THE INVENTION

The invention relates to an electrical connector. More specifically, the invention relates to an electrical connector assembly having a plug connector and a cap connector.

### DESCRIPTION OF THE PRIOR ART

An example of an electrical connector assembly mounted between two printed circuit boards that face each other for use in personal computers and the like is disclosed in U.S. Pat. No. 6,159,021. The electrical connector assembly includes a plug connector mounted on a first circuit board and a cap connector mounted on a second circuit board that faces the first circuit board and engages the plug connector. The plug connector has an insulative housing and a plurality of elastic contacts arranged on both sides of a central wall of the insulative housing. The cap connector has an insulative housing for receiving and engaging the insulative housing of the plug connector and a plurality of planar contacts for electrically contacting the elastic contacts. The planar contacts are arranged in two lines facing each other and correspond to the elastic contacts. Exterior sides of the elastic contacts contact the planar contacts on a 1 to 1 basis. When the elastic contacts contact the planar contacts, the elasticity of the elastic contacts, that is, the contact force, urges the planar contacts toward the exterior. The outwardly urging contact force is applied to an exterior wall of the cap connector, which supports the planar contacts from the exteriors thereof.

As a result of advances in the functionality of electrical equipment, there is an increased need to mount a higher quantity of circuit boards in electrical equipment and thereby miniaturize the electrical connector assemblies of the type described above. In the existing electrical connector assembly, however, it is necessary that the outer wall of the insulative housing of the cap connector be of a thickness capable of withstanding the contact force exerted thereon during engagement with the plug connector. Specifically, as the number of contacts increases, the contact force also increases, and there is a risk that the outer wall of the insulative housing may deform or be damaged. Accordingly, the outer wall of the insulative housing of the cap connector must be made of a sturdy construction or a thickness capable of withstanding the increased contact force. The size of the electrical connector assembly, therefore, must be large, which limits the degree of miniaturization capable for the electrical connector assembly and the cap connector. In addition, it is necessary to insert the plug connector so that the planar contacts correspond to the elastic contacts, while changing the orientations thereof making operability during assembly difficult.

It is therefore desirable to develop an electrical connector assembly wherein the electrical connector assembly and the cap connector utilized thereby may be miniaturized without risk of deformation of the wall of the insulative housing even if the wall of the-cap connector is made thin. It is further desirable to provide an electrical connector assembly and a cap connector utilized thereby, wherein operability during assembly is improved.

### SUMMARY OF THE INVENTION

The invention relates to an electrical connector assembly having a plug connector and a cap connector. The plug connector includes an insulative plug housing with an engagement protrusion and a plurality of elastic first contacts. The cap connector includes an insulative cap housing with an engagement recess for receiving the engagement protrusion. Planar second contacts are arranged within the engagement recess. Each of the second contacts has a pair of contact portions that maintains an interval therebetween. One of the pair of contact portions contacts the first contacts and the other of the pair of contact portions contacts the engagement protrusion to support a biasing force caused by the contact of the first and second contacts when the plug connector and the cap connector are engaged.

### BRIEF DESCRIPTION OF THE DRAWINGS

FIG. 1 is a front plan view of a plug connector.

FIG. 2 is a top plan view of the plug connector of FIG. 1.

FIG. 3 is a bottom plan view of the plug connector of FIG. 1.

FIG. 4 is a side plan view of the plug connector of FIG. 1.

FIG. 5A is a magnified sectional view taken along line 5a-5a of FIG. 1.

FIG. 5B is a magnified sectional view taken along line 5b-5b of FIG. 1.

FIG. 6 is a front plan view of a cap connector.

FIG. 7 is a top plan view of the cap connector of FIG. 6.

FIG. 8 is a side plan view of the cap connector of FIG. 6.

FIG. 9 is a magnified sectional view taken along line 9-9 of FIG. 6.

FIG. 10 is a sectional view of an electrical connector assembly wherein the plug connector and the cap connector are engaged.

### DETAILED DESCRIPTION OF THE PREFERRED EMBODIMENT

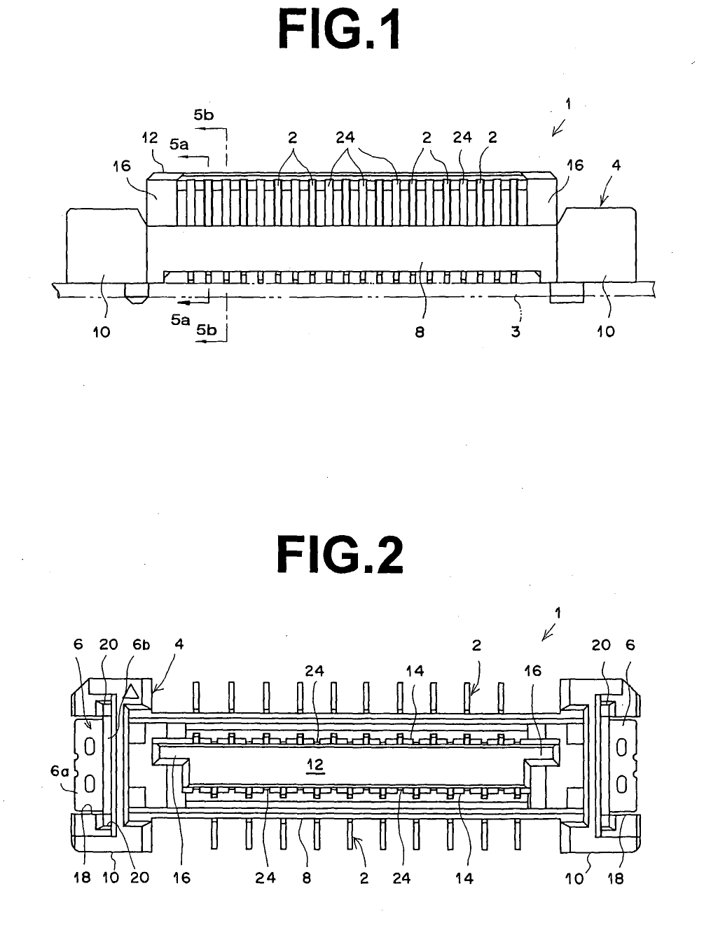

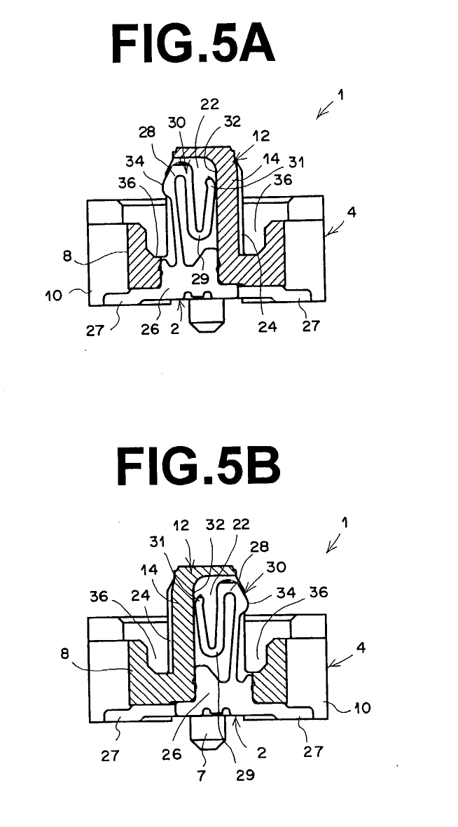

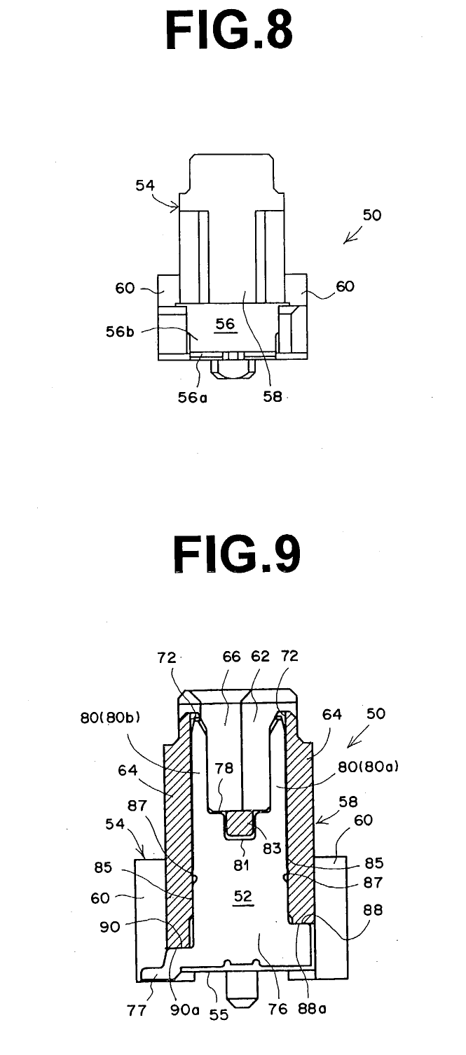

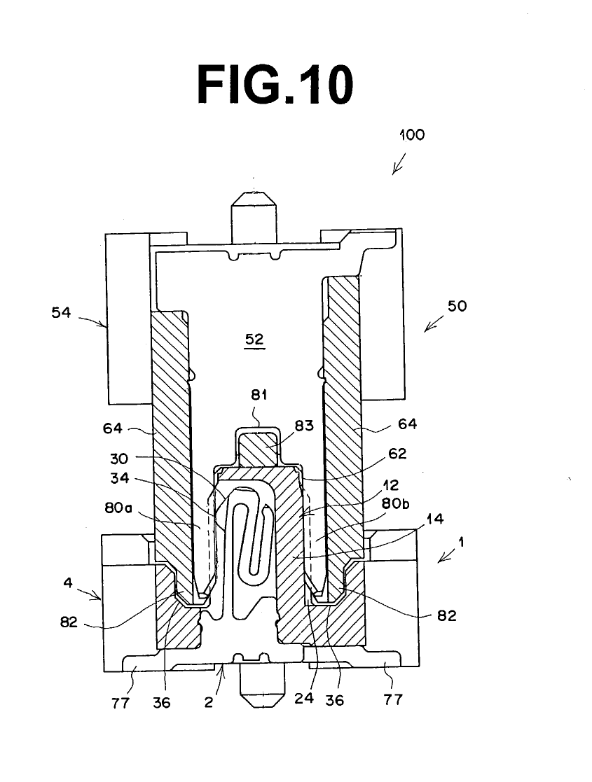

FIG. 10 shows an electrical connector assembly 100. The electrical connector assembly 100 includes a plug connector 1 and a cap connector 50. The plug connector 1 will first be described in greater detail with reference to FIGS. 1 though 4. The cap connector 50 will then be described in greater detail with reference to FIGS. 5 through 9.

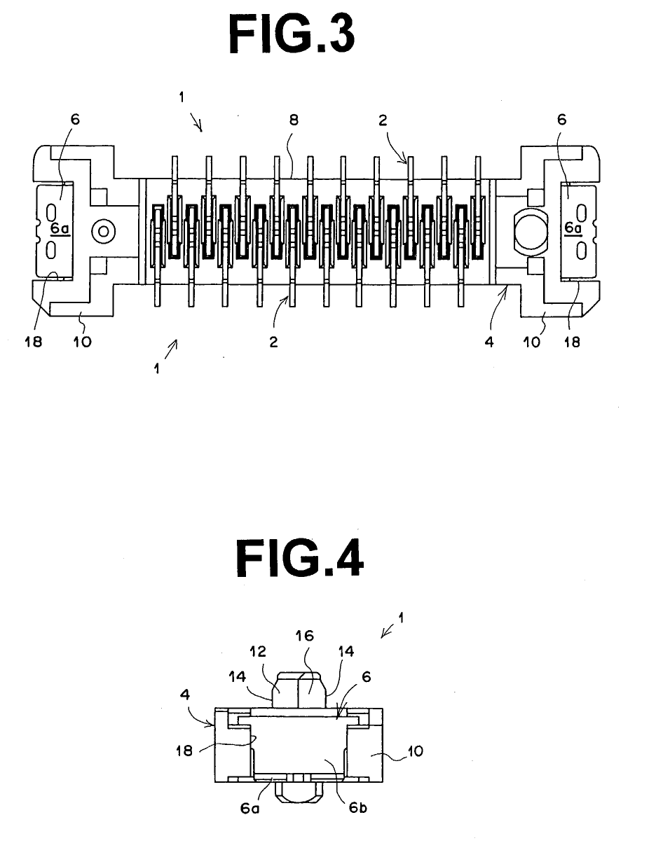

As shown in FIGS. 1 through 4, the plug connector 1 has an insulative plug housing 4 provided with a plurality of elastic first contacts 2. The plug housing 4 has an elongated main body 8. An engagement protrusion 12 is arranged perpendicular to a circuit board 3 at substantially a center of the main body 8 in the longitudinal direction thereof and is integrally formed therewith. The engagement protrusion 12 has a substantially inverted T-shape in a cross section taken in a direction perpendicular to the longitudinal direction of the main body 8. The first contacts 2 are arranged alternately on both sidewalls 14 of the engagement protrusion 12 in a zigzag manner with respect to the longitudinal direction thereof, as best shown in FIG. 3. As best shown in FIG. 2, ribs 16 are formed at both longitudinal ends of the engagement protrusion 12 and at positions deviated from a centerline (not shown) in the longitudinal direction of the engagement protrusion 12. The ribs 16 act as keying guides during engagement with the cap connector 50, to be described later, to prevent erroneous assembly of the plug connector 1 with the cap connector 50.

Mounting portions 10 that are wider than the main body 8 are provided at both ends of the plug housing 4 and are formed integrally therewith. Rectangular recesses 18, which are open toward an exterior in the longitudinal direction of the plug housing 4, are formed in each of the mounting portions 10. Grooves 20 are formed so that they face each other in the interior sides of the rectangular recesses 18 in directions perpendicular to the circuit board 3. Mounting members 6 extend from the plug housing 4 for soldering the plug housing 4 to the circuit board 3. The mounting members 6 are arranged within the recesses 18. The mounting members 6 are substantially L-shaped in cross section and have a solder foot 6a and a press-fit portion 6b, as best shown in FIG. 2. The solder foot 6a is soldered onto conductive pads (not shown) of the circuit board 3 and the press fit portion 6b is press-fit into the grooves 20.

As shown in FIGS. 5A and 5B, a plurality of contact housing grooves 22 are open to one side of the engaging protrusion 12 and are formed therein. A plurality of support grooves 24 that extend in a direction perpendicular to the circuit board 3 are formed on the sidewall 14 corresponding to the housing grooves 22. The adjacent first contacts 2 and the support grooves 24 are arranged to be in a reverse orientation in a horizontal direction, that is, the first contacts 2 are always paired with a support groove 24. In addition, grooves 36 are formed on the lower portion of the engaging protrusion 12 and along the longitudinal direction thereof. In this manner, the first contacts 2 and the support grooves 24 are arranged at the same position with respect to the longitudinal direction of the plug housing 4. Adjacent first contacts 2 are arranged by press-fitting into adjacent housing grooves 22 in a reverse orientation. As a result, the first contacts 2 and the support grooves 24 are alternately arranged along the longitudinal direction of the plug housing 4.

The first contacts 2 arranged in the housing grooves 22 are of a shape similar to the contacts disclosed in U.S. Pat. No. 6,159,021 described herein. As best shown in FIGS. 5A and 5B, each of the first contacts 2 has a base 26, a tine 27, and a contact portion 30. The base 26 is press-fit within the housing groove 22. The tine 27 extends toward the circuit board 3 from the base 26 and is soldered thereto. The contact portion 30 extends within the housing groove 22 from the base 26 and has a first bent portion 28, a second bent portion 29, and a tip 31. The tip 31 is in contact with an inner wall 32 of the housing groove 22 so that elasticity is imparted to the contact portion 30. A contact point 34 that projects outward from the sidewall 14 is formed in the vicinity of the first bent portion 28. The contact point 34 contacts a second contact 52 of the cap connector 50, to be described later.

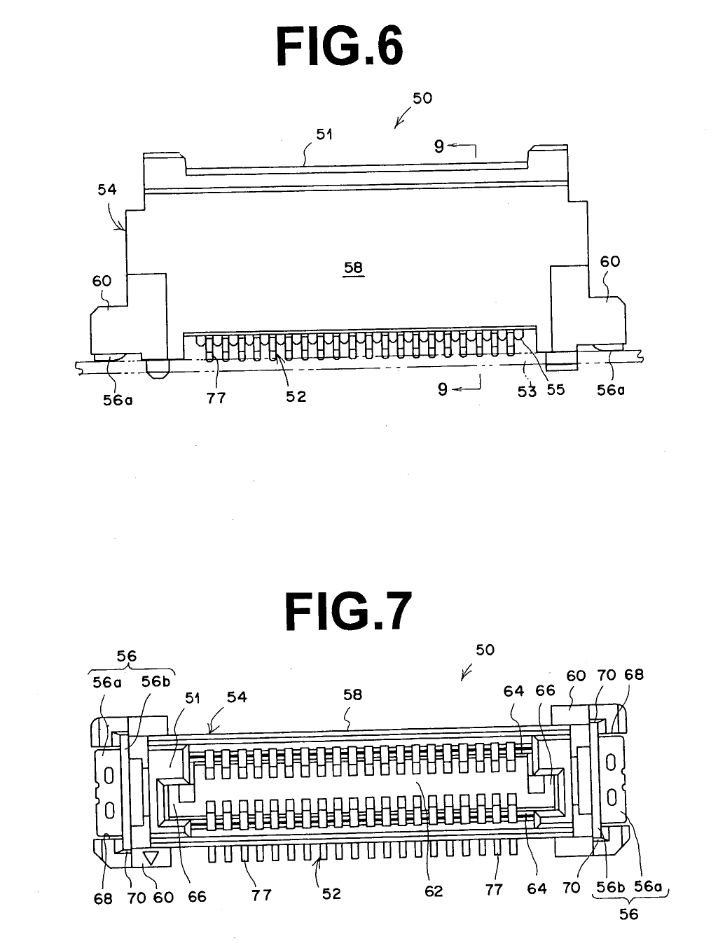

As shown in FIGS. 6 through 9, the cap connector 50 has a substantially rectangular insulative cap housing 54. The cap housing 54 has a substantially rectangular main body 58 and mounting portions 60 wider than the main body 58 provided at both ends thereof and integrally formed therewith. An engagement recess 62, as shown in FIGS. 7 and 9, opens at an upper surface 51 of the main body 58 along a longitudinal direction thereof. The engagement recess 62 has dimensions complementary to the engagement protrusion 12 of the plug connector 1 for receipt therein. As shown in FIG. 9, contact housing grooves 72 are formed in a bottom surface 55 of the cap housing 54. The contact housing grooves 72 communicate with the engagement recess 62. Spaces between adjacent contact housing grooves 72 are formed as partition walls. Planar second contacts 52, to be described later, are arranged along the longitudinal direction on the inner surfaces of both sidewalls 64 of the engagement recess 62.

As shown in FIG. 7, cutouts 66 are formed at both ends of the engagement recess 62. The cutouts 66 are formed to enable receipt of the ribs 16 of the plug connector 1 therein. Rectangular recesses 68 that face an exterior in the longitudinal direction of the cap housing 54 are formed on each of the mounting portions 60, in a similar manner to those of the plug connector 1. Mounting members 56 are arranged within the rectangular recesses 68. Grooves 70, which are perpendicular to a circuit board 53, shown in FIG. 6, are formed on an interior of the rectangular recesses 68. The mounting members 56 are substantially L-shaped in cross section and have a solder foot 56a and a press-fit portion 56b. The solder foot 56a is soldered onto the circuit board 53. The press-fit portion 56b is press-fit into the grooves 70.

As best shown in FIG. 9, each of the second contacts 52 is formed by being punched out of a single metal plate. Each of the second contacts 52 has a base 76, a tine 77, and a pair of symmetrically formed contact sections 80. The tine 77 extends from the base 76 toward the circuit board 53. The pair of contact sections 80 is formed to extend upward and away from the circuit board 53 from the sides of the base 76 and is formed integrally therewith. The contact sections 80 are separated from each other, and the interval therebetween is uniformly maintained. The engagement protrusion 12 of the plug connector 1 is received between the pair of contact sections 80. Outer edges 85 of the base 76 and the contact sections 80 are positioned co-linearly. Barbs 87 are formed on the outer edges 85 such that the base 76 has an interference fit with the inner-walls of the housing 54 when press-fit therein. Upward facing shoulders 88, 90 are formed on sides of the base 76 and at lower portions thereof. The shoulders 88, 90 abut downward facing abutment surfaces 88a, 90a provided on the cap housing 54 and position the second contacts 52.

A rectangular cutout 81 is formed on an upper edge 78 of the base 76 between the pair of contact sections 80.

Positioning portions 83 of a complimentary shape to the rectangular cutout 81 are formed integrally with the cap housing 54. The positioning portions 83 connect the partition walls and project within the contact housing grooves 72. The rectangular cutouts 81 and the positioning portions 83 engage to stabilize the positions of the contact sections 80 in horizontal and vertical directions.

Because the tine 77 is formed on only one side of the base 76, insertion into the housing 54 becomes one-directional, thereby facilitating assembly of the cap connector 50. In addition, because the tine portions 77 protrude from only one side of the cap housing 54, when the cap housing 54 is mounted onto the circuit board 53, an effect is obtained wherein the design of the circuitry on the circuit board 53 can be simplified.

Mating of the cap connector 50 and the plug connector 1 will now be described in greater detail with reference to FIG. 10. As shown in FIG. 10, when the plug connector 1 and the cap connector 50 are mated, distal ends 82 of the cap connector 50 are seated within the grooves 36 of the plug connector 1, and the engagement protrusion 12 of the plug connector 1 is housed within the engagement recess 62 of the cap connector 50 such that the contact sections 80 of the second contacts 52 contact the contact portions 30 of the first contacts 2. A left contact portion (the left in FIG. 10) of the second contact 52 contacts the contact point 34 of the first contact 2, and a right contact portion 80b is inserted into the support groove 24 in the side wall 14 of the engagement protrusion 12. The elastic urging force generated by the contact between the contact point 34 and the contact portion 80a operates to move the other contact portion 80b toward the engagement protrusion 12. As a result, the force that moves the contact portion 80b is supported by the sidewall 14 of the engagement 10 protrusion 12 with which the contact portion 80b is in contact.

Because the sidewall 64 of the cap connector 50, which is in contact with the contact portion 20a, does not directly receive the contact force generated by the contact between the first and second contacts 2, 52, the contact force is received solely by the second contacts 52. Accordingly, the contact force generated by the contact between the first and second contacts 2, 52 is not exerted on the cap housing 54 that supports the second contacts 52. Even in the case where the contact force is exerted on the cap housing 54, the amount of pressure is slight. Because there is no risk of deformation or damage to the cap housing 54, even if the wall thereof is made thin, miniaturization of the electrical connector assembly 100 and the cap connector 50 is possible.

In addition, in the case that the second contacts 52 arranged within the cap housing 54 are constructed to have tine portions 77 protruding only from one side of the cap housing 54, the necessity to alternate the orientation of the second contacts 52 when the plug connector 1 is inserted into the cap housing 54 is obviated. Therefore, the insertion of the second contacts 52 is facilitated, and a miniature electrical connector assembly 100 and cap connector 50 having improved operability during assembly is obtained.

The foregoing illustrates some of the possibilities for practicing the invention. Many other embodiments are possible within the scope and spirit of the invention. It is, therefore, intended that the foregoing description be regarded as illustrative rather than limiting, and that the scope of the invention is given by the appended claims together with their full range of equivalents.

I/we claim:

1. An electrical connector assembly, comprising:
a plug connector having an insulative plug housing with an engagement protrusion and a plurality of elastic first contacts; and
a cap connector having an insulative cap housing with an engagement recess for receiving the engagement protrusion and planar second contacts arranged within the engagement recess, each of the second contacts having a pair of contact portions that maintain an interval therebetween such that one of the pair of contact portions contacts the first contacts and the other of the pair of contact portions contacts the engagement protrusion to support a biasing force caused by the contact of the first and second contacts.

2. The electrical connector assembly of claim 1, wherein the first contacts are alternately arranged on both sides of the engagement protrusion.

3. The electrical connector assembly of claim 1, wherein the engagement protrusion has a T-shaped cross section.

4. The electrical connector assembly of claim 1, wherein the engagement protrusion includes a rib for guiding the engagement protrusion into the engagement recess.

5. The electrical connector assembly of claim 1, wherein the engagement protrusion includes contact housing grooves open toward one side in which the first contacts are arranged.

6. The electrical connector assembly of claim 1, wherein the pair of contact portions flank the engagement protrusion when the plug connector and cap connector are engaged.

7. The electrical connector assembly of claim 1, wherein the second contacts include tine portions that protrude from only one side of the cap housing.

8. The electrical connector assembly of claim 1, wherein each of the pair of contact portions is symmetrical.

9. The electrical connector assembly of claim 1, wherein the cap housing includes a positioning portion that extends between the pair of contact portions to stabilize the pair of contact portions.

10. The electrical connector assembly of claim 1, wherein the second contacts include barbs on an outer surface for press-fitting the second contacts into the cap housing.

11. A cap connector, comprising:
an insulative cap housing with planar contacts arranged within an engagement recess, each of the contacts having spaced apart first and second contact portions that maintain an interval therebetween such that when the first contact portion contacts a plug connector contact, the second contact portion is biased toward the first contact portion.

12. The cap connector of claim 11, wherein the contacts include tine portions that protrude from only one side of the cap housing.

13. The cap connector of claim 11, wherein the first and second contact portions are symmetrical.

14. The cap connector of claim 11, wherein the cap housing includes a positioning portion that extends between the first and second contact portions to stabilize the contact portions in a vertical and horizontal direction.

15. The cap connector of claim 11, wherein the contacts include barbs on an outer surface for press-fitting the contacts into the cap housing.

16. The cap connector of claim 11, wherein the contacts have shoulders that abut the cap housing to position the contacts.
